(19) United States
(12) Patent Application Publication
(10) Pub. No.: US 2021/0257283 A1
(43) Pub. Date: Aug. 19, 2021

(54) NOTEBOOK BATTERY PROTECTION CIRCUIT PACKAGE AND METHOD OF FABRICATING THE SAME

(71) Applicant: ITM SEMICONDUCTOR CO., LTD., Chungcheongbuk-do (KR)

(72) Inventors: Hyuk Hwi NA, Chungcheongbuk-do (KR); Ho Seok HWANG, Gyeonggi-do (KR); Ja Guen GU, Chungcheongbuk-do (KR); Chi Sun SONG, Chungcheongbuk-do (KR); Seong Hwan JEONG, Chungcheongbuk-do (KR); Hyeon Soo CHOI, Chungcheongbuk-do (KR)

(21) Appl. No.: 17/178,364

(22) Filed: Feb. 18, 2021

(30) Foreign Application Priority Data
Feb. 18, 2020 (KR) 10-2020-0019899

(51) Int. Cl. H01L 23/495; H02J 7/00; H05K 1/18; H05K 3/30; H05K 3/28; H01L 23/31; H01L 21/48; H01L 21/56

(52) U.S. Cl. CPC H01L 23/49575; H02J 7/0031; H05K 1/185; H05K 3/30; H05K 3/284; H05K 2201/10166; H01L 23/49503; H01L 23/4952; H01L 21/4825; H01L 21/565; H01L 23/3107

(57) ABSTRACT

Provided is a notebook battery protection circuit package including a package substrate, a fuel gauge integrated circuit (FGIC) module mounted on the package substrate, a protection integrated circuit (IC) module mounted on the package substrate, a charge/discharge transistor module mounted on the package substrate, and a mold provided on the package substrate to encapsulate the FGIC module, the protection IC module, and the charge/discharge transistor module into one.

### CROSS-REFERENCE TO RELATED PATENT APPLICATION

This application claims the benefit of Korean Patent Application No. 10-2020-0019899, filed on Feb. 18, 2020, in the Korean Intellectual Property Office, the disclosure of which is incorporated herein in its entirety by reference.

### BACKGROUND

### 1. Field

The present invention relates to a battery control system and, more particularly, to a notebook battery protection circuit package and a method of fabricating the same.

### 2. Description of the Related Art

Batteries are generally used in electronic devices such as mobile phones, personal digital assistants (PDAs), smart watches, and notebook computers. As a battery most commonly used in mobile devices, etc., a lithium ion battery is heated when overcharge or overcurrent occurs, and experiences performance degradation and even has the risk of explosion when heating is continued to increase the temperature thereof. Accordingly, a battery protection circuit for controlling battery operation is required to prevent the performance degradation.

For a notebook, a battery control circuit may be configured by mounting a protection integrated circuit (IC), a fuel gauge IC (FGIC), a fuse field effect transistor (FET), etc. for detecting and blocking overcharge, overdischarge, and overcurrent of a battery, on a printed circuit board (PCB).

Therefore, in general, because a plurality of ICs need to be individually packaged and mounted on a PCB to control a battery and thus a battery control circuit is increased in volume, a small size and a light weight of a notebook may not be easily achieved and a problem may be caused in heat dissipation efficiency. Furthermore, a space for increasing the capacity of battery cells may not be easily ensured.

### RELATED ART DOCUMENTS

### Patent Documents

(Patent document 1) 1. Korean Patent Publication No. 10-2009-0117315 (Nov. 12, 2009)

(Patent document 2) 2. Korean Patent Publication No. 10-2015-0035266 (Apr. 6, 2015)

### SUMMARY

The present invention provides a notebook battery protection circuit package capable of achieving a small size to increase a design margin and of efficiently managing a battery, and a method of fabricating the same. However, the scope of the present invention is not limited thereto.

According to an aspect of the present invention, there is provided a notebook battery protection circuit package including a package substrate, a fuel gauge integrated circuit (FGIC) module mounted on the package substrate, a protection integrated circuit (IC) module mounted on the package substrate, a charge/discharge transistor module mounted on the package substrate, and a mold provided on the package substrate to encapsulate the FGIC module, the protection IC module, and the charge/discharge transistor module into one.

The package substrate may include a lead frame including a die mount and input/output (I/O) terminals, the FGIC module, the protection IC module, and the charge/discharge transistor module may be mounted on the die mount of the lead frame, and the mold may expose at least portions of the I/O terminals.

The FGIC module may include a first wafer having a FGIC device thereon, the protection IC module may include a second wafer having a protection IC device thereon, and the first and second wafers may be mounted on the package substrate at a wafer level.

The charge/discharge transistor module may include a third wafer having at least one charge/discharge field effect transistor (FET) thereon, and the third wafer may be mounted on the package substrate at a wafer level.

The third wafer may be directly mounted on the package substrate, and the second wafer may be mounted on the third wafer.

The notebook battery protection circuit package may further include a fuse transistor module mounted on the package substrate, the mold may further encapsulate the fuse transistor module, the fuse transistor module may include a fourth wafer having at least one fuse FET thereon, and the fourth wafer may be mounted on the package substrate at a wafer level.

The notebook battery protection circuit package may further include a diode module mounted on the package substrate, the mold may further encapsulate the diode module, the diode module may include a fifth wafer having at least one diode thereon, and the fifth wafer may be mounted on the package substrate at a wafer level.

The notebook battery protection circuit package may further include at least one passive device mounted on the package substrate, and the mold may further encapsulate the passive device.

The notebook battery protection circuit package may further include a connector connected to a side of the package substrate and exposed from the mold.

According to another aspect of the present invention, there is provided a method of fabricating a notebook battery protection circuit package, the method including mounting a fuel gauge integrated circuit (FGIC) module on a package substrate, mounting a protection integrated circuit (IC) module on the package substrate, mounting a charge/discharge transistor module on the package substrate, and forming a mold on the package substrate to encapsulate the FGIC module, the protection IC module, and the charge/discharge transistor module into one.

The package substrate may include a lead frame including a die mount and input/output (I/O) terminals, the FGIC module, the protection IC module, and the charge/discharge transistor module may be mounted on the die mount of the lead frame, and, in the forming of the mold, at least portions of the I/O terminals may be exposed from the mold.

The FGIC module may include a first wafer having a FGIC device thereon, the protection IC module may include a second wafer having a protection IC device thereon, and, in the mounting of the FGIC module and the protection IC module, the first and second wafers may be mounted on the package substrate at a wafer level.

The charge/discharge transistor module may include a third wafer having at least one charge/discharge field effect transistor (FET) thereon, and, in the mounting of the charge/discharge transistor module, the third wafer may be mounted on the package substrate at a wafer level.

The third wafer may be directly mounted on the package substrate, and the second wafer may be mounted on the third wafer.

The method may further include mounting a fuse transistor module on the package substrate, in the forming of the mold, the mold further encapsulates the fuse transistor module, the fuse transistor module may include a fourth wafer having at least one fuse FET thereon, and, in the mounting of the fuse transistor module, the fourth wafer may be mounted on the package substrate at a wafer level.

The method may further include mounting a diode module on the package substrate, the mold may further encapsulate the diode module, the diode module may include a fifth wafer having at least one diode thereon, and, in the mounting of the diode module, the fifth wafer may be mounted on the package substrate at a wafer level.

The method may further include mounting at least one passive device on the package substrate, and the mold may further encapsulate the passive device.

### BRIEF DESCRIPTION OF THE DRAWINGS

The above and other features and advantages of the present invention will become more apparent by describing in detail embodiments thereof with reference to the attached drawings in which:

FIG. 1 is a cross-sectional view of a battery protection circuit package according to an embodiment of the present invention;

FIG. 2 is a cross-sectional view of a battery protection circuit package according to another embodiment of the present invention;

FIG. 3 is a perspective view of a battery protection circuit package according to another embodiment of the present invention;

FIG. 4 is a plan view of a battery protection circuit package according to another embodiment of the present invention; and

FIG. 5 is a flowchart of a method of fabricating a battery protection circuit package, according to an embodiment of the present invention.

### DETAILED DESCRIPTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity or convenience of explanation.

It will be understood that when an element, such as a layer, a region, or a substrate, is referred to as being “on”, “connected to”, “stacked on”, or “coupled to” another element, it may be directly on, connected to, stacked on, or coupled to the other element or intervening elements may be present. In contrast, when an element is referred to as being “directly on”, “directly connected to”, “directly stacked on”, or “directly coupled to” another element or layer, there are no intervening elements or layers present. Like reference numerals denote like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “above”, “upper”, “beneath”, “below”, “lower”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

FIG. 1 is a cross-sectional view of a battery protection circuit package 100 according to an embodiment of the present invention.

Referring to FIG. 1, the battery protection circuit package 100 may include a package substrate 110, a fuel gauge integrated circuit (FGIC) module 120, a protection integrated circuit (IC) module 130, a charge/discharge transistor module 140, and a mold 170.

The package substrate 110 is a substrate used to mount components thereon and having wires for connecting the components and may include, for example, a printed circuit board (PCB) or a lead frame.

The PCB is a rigid substrate structure and may include a structure in which a circuit pattern is provided on a core structure. Furthermore, the PCB may include via electrodes to electrically connect components mounted at an upper side to a lower side. The PCB may further include a wiring pattern for rewiring the via electrodes, and external terminals connected to the wiring pattern.

Unlike the PCB, the lead frame itself may be patterned into circuit wires and input/output (I/O) terminals. Furthermore, the lead frame may serve as a heatsink and thus be useful for heat dissipation.

The FGIC module 120 may be mounted on the package substrate 110. For example, the FGIC module 120 may be mounted on the package substrate 110 as a single component or as multiple components. For example, the FGIC module 120 may be mounted on the package substrate 110 by using surface mount technology (SMT).

The FGIC module 120 may provide data such as battery state of charge, available capacity, remaining capacity, lifetime, discharge time, number of charges/discharges, predicted lifetime, and battery resistance to a system.

Furthermore, the FGIC module 120 may further include a battery protection IC. The battery protection IC may protect the battery from overcharge, overdischarge, overcurrent, etc. of the battery.

The protection IC module 130 may be mounted on the package substrate 110. For example, the protection IC module 130 may be mounted on the package substrate 110 as a single component or as multiple components. For example, the protection IC module 130 may be mounted on the package substrate 110 by using SMT.

The protection IC module 130 may protect the battery from overcharge, overdischarge, overcurrent, overvoltage, etc. of the battery. In an embodiment, when the FGIC module 120 includes the battery protection IC, the protection IC module 130 may operate as a secondary protection IC.

The charge/discharge transistor module 140 may be mounted on the package substrate 110. For example, the charge/discharge transistor module 140 may be mounted on the package substrate 110 as a single component or as multiple components. The charge/discharge transistor module 140 may be mounted on the package substrate 110 by using SMT.

For example, the FGIC module 120 or the protection IC module 130 may monitor a voltage of the battery and control an on/off operation of the charge/discharge transistor module 140 to control a charge or discharge operation. Specifically, the FGIC module 120 or the protection IC module 130 may turn off the charge/discharge transistor module 140 when overcurrent or overdischarge is detected in a battery discharge operation or when overcurrent or overcharge is detected in a battery charge operation.

The mold 170 may be provided on the package substrate 110 to encapsulate the FGIC module 120, the protection IC module 130, and the charge/discharge transistor module 140. For example, the mold 170 may be a single structure for simultaneously encapsulating the FGIC module 120, the protection IC module 130, and the charge/discharge transistor module 140 into one.

The mold 170 may expose external terminals of the package substrate 110. For example, the mold 170 may expose at least portions of the external terminals of the PCB or the I/O terminals of the lead frame.

For example, the mold 170 may be made of an epoxy molding compound (EMC).

According to the current embodiment, by packaging the FGIC module 120, the protection IC module 130, and the charge/discharge transistor module 140, which were individually packaged, into a single package, the battery protection circuit package 100 may simplify a structure and reduce an interface thereof to achieve a reduction in size, and thus products using the same may improve space utilization to increase a design margin.

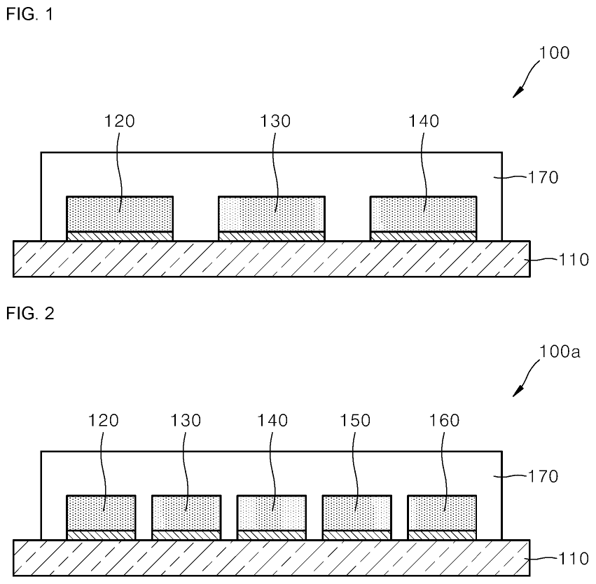

FIG. 2 is a cross-sectional view of a battery protection circuit package 100a according to another embodiment of the present invention. The battery protection circuit package 100a according to the current embodiment is obtained by adding some elements to the battery protection circuit package 100 of FIG. 1, and thus the description provided above in relation to FIG. 1 will not be repeated herein.

Referring to FIG. 2, the battery protection circuit package 100a may further include a fuse transistor module 150 and/or a diode module 160 in addition to the FGIC module 120, the protection IC module 130, and the charge/discharge transistor module 140.

The fuse transistor module 150 may be mounted on the package substrate 110. The fuse transistor module 150 is a module for controlling a fuse used to control a battery of a notebook or the like. The fuse may be included in the battery protection circuit package 100a or be provided outside the battery protection circuit package 100a.

The diode module 160 may be mounted on the package substrate 110. The diode module 160 may also be used as a rectifier.

The mold 170 may be provided on the package substrate 110 to encapsulate the FGIC module 120, the protection IC module 130, the charge/discharge transistor module 140, the fuse transistor module 150, and the diode module 160. For example, the mold 170 may be a single structure for encapsulating the FGIC module 120, the protection IC module 130, the charge/discharge transistor module 140, the fuse transistor module 150, and the diode module 160 into one.

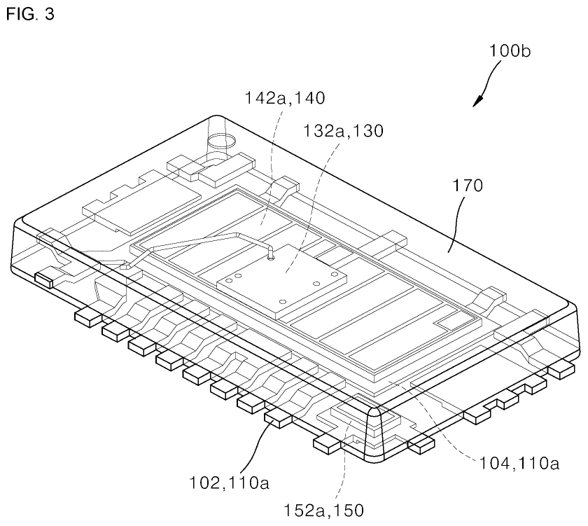

FIG. 3 is a perspective view of a battery protection circuit package 100b according to another embodiment of the present invention. The battery protection circuit package 100b according to the current embodiment is obtained by specifying or modifying some elements of the battery protection circuit packages 100 and 100a of FIGS. 1 and 2, and thus the description provided above in relation to FIGS. 1 and 2 will not be repeated herein.

Referring to FIG. 3, the battery protection circuit package 100b may use a lead frame 110a as the package substrate 110, and include the protection IC module 130, the charge/discharge transistor module 140, and the fuse transistor module 150.

For example, the lead frame 110a may include a die mount 104 and I/O terminals 102. The die mount 104 may be used to mount components thereon. For example, at least one or all of the protection IC module 130, the charge/discharge transistor module 140, and the fuse transistor module 150 may be mounted on the die mount 104 of the lead frame 110a.

Furthermore, the die mount 104 may be divided into one or more pieces based on the number of components mounted thereon. For example, the charge/discharge transistor module 140 may be mounted on a portion of the die mount 104, and the fuse transistor module 150 may be mounted on another portion of the die mount 104. The protection IC module 130 may be mounted on the charge/discharge transistor module 140.

Specifically, the protection IC module 130 may include a second wafer 132a having a protection IC device thereon. Specifically, the second wafer 132a may refer to a structure in which a protection IC device is formed on a semiconductor wafer by using a semiconductor IC process.

The second wafer 132a may be mounted on the package substrate 110, e.g., the lead frame 110a, at the wafer level. Herein, being mounted at the wafer level may mean that the second wafer 132a is mounted on the lead frame 110a in a wafer state without being individually packaged.

The charge/discharge transistor module 140 may include a third wafer 142a having at least one charge/discharge field effect transistor (FET) thereon. Specifically, the third wafer 142a may refer to a structure in which a charge/discharge FET is formed on a semiconductor wafer by using a semiconductor IC process.

The third wafer 142a may be mounted on the package substrate 110, e.g., the lead frame 110a, at the wafer level. Herein, being mounted at the wafer level may mean that the third wafer 142a is mounted on the lead frame 110a in a wafer state without being individually packaged.

Furthermore, the third wafer 142a may be directly mounted on the package substrate 110, e.g., the lead frame 110a, and the second wafer 132a may be mounted on the third wafer 142a. Herein, the fact that the third wafer 142a is directly mounted on the lead frame 110a means that another wafer or structure is not interposed but solder or adhesive required in a mounting process may be interposed therebetween.

In this manner, the size, e.g., a footprint, of the lead frame 110a may be reduced by mounting the second and third wafers 132a and 142a on the lead frame 110a in a stacked structure.

The fuse transistor module 150 may include a fourth wafer 152a having at least one fuse FET thereon. Specifically, the fourth wafer 152a may refer to a structure in which a fuse FET is formed on a semiconductor wafer by using a semiconductor IC process.

The fourth wafer 152a may be mounted on the package substrate 110, e.g., the lead frame 110a, at the wafer level. Herein, being mounted at the wafer level may mean that the fourth wafer 152a is mounted on the lead frame 110a in a wafer state without being individually packaged.

The second to fourth wafers 132a, 142a, and 152a may include I/O pads, and these I/O pads may be connected to each other or be electrically connected to the lead frame 110a by using appropriate connection means, e.g., wire bonding or ball bonding.

The mold 170 may be provided on the lead frame 110a to encapsulate the second to fourth wafers 132a, 142a, and 152a and expose at least portions of the I/O terminals 102.

The battery protection circuit package 100b may not include passive devices. In this case, when used in a product, the battery protection circuit package 100b needs to be connected to another structure including the passive devices. For example, the battery protection circuit package 100b may be mounted on a main board including the passive devices.

The above-described battery protection circuit package 100b may be used in products having various configurations of the passive devices. In this case, the battery protection circuit package 100b may provide common ICs and various configurations of the passive devices may be provided on the main board appropriately for the products.

Meanwhile, in an embodiment modified from the current embodiment, the battery protection circuit package 100b may further include the FGIC module 120.

The battery protection circuit package 100b according to the current embodiment may be reduced in size by mounting the protection IC module 130, the charge/discharge transistor module 140, and the fuse transistor module 150 on one lead frame 110a into a single package, and be further reduced in size by mounting the second to fourth wafers 132a, 142a, and 152a at the wafer level in a partially stacked structure.

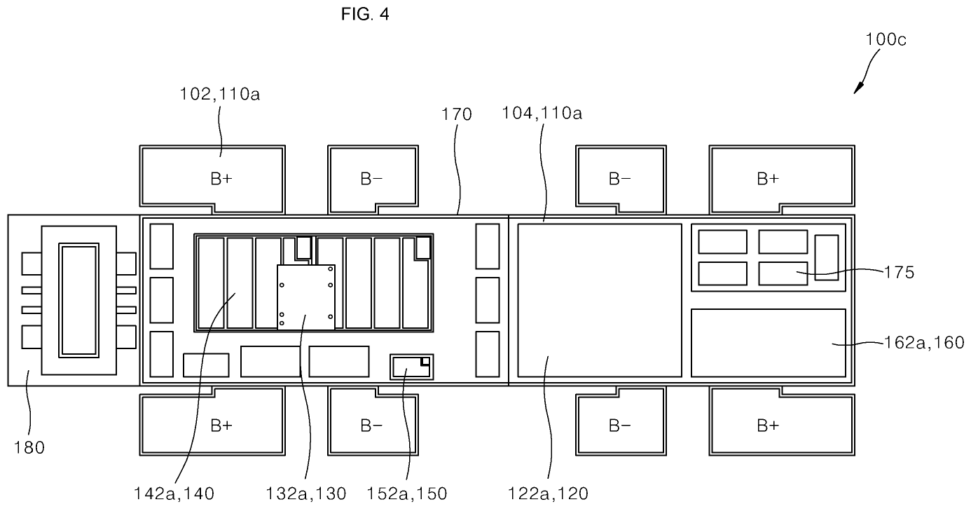

FIG. 4 is a plan view of a battery protection circuit package 100c according to another embodiment of the present invention. The battery protection circuit package 100c according to the current embodiment is obtained by specifying, adding, or modifying some elements of the above-described battery protection circuit packages 100, 100a, and 100b, and thus the description provided above in relation to FIGS. 1 to 3 will not be repeated herein.

Referring to FIG. 4, the battery protection circuit package 100c may use the lead frame 110a as the package substrate 110, and include the FGIC module 120, the protection IC module 130, the charge/discharge transistor module 140, the fuse transistor module 150, and the diode module 160 mounted on the lead frame 110a.

The FGIC module 120 may include a first wafer 122a having a FGIC device thereon. Specifically, the first wafer 122a may refer to a structure in which a FGIC device is formed on a semiconductor wafer by using a semiconductor IC process. The first wafer 122a may be mounted on the package substrate 110, e.g., the lead frame 110a, at the wafer level. Herein, being mounted at the wafer level may mean that the first wafer 122a is mounted on the lead frame 110a in a wafer state without being individually packaged.

As described above in relation to FIG. 3, the protection IC module 130 may include the second wafer 132a having a protection IC device thereon, the charge/discharge transistor module 140 may include the third wafer 142a having at least one charge/discharge FET thereon, and the fuse transistor module 150 may include the fourth wafer 152a having at least one fuse FET thereon. As described above, the second to fourth wafers 132a, 142a, and 152a may also be mounted on the lead frame 110a at the wafer level.

Furthermore, the diode module 160 may include a fifth wafer 162a having at least one diode thereon. Specifically, the fifth wafer 162a may refer to a structure in which a diode is formed on a semiconductor wafer by using a semiconductor IC process.

The fifth wafer 162a may be mounted on the package substrate 110, e.g., the lead frame 110a, at the wafer level. Herein, being mounted at the wafer level may mean that the fifth wafer 162a is mounted on the lead frame 110a in a wafer state without being individually packaged.

Furthermore, at least one passive device 175, e.g., a resistor, a capacitor, and/or an inductor, may be mounted on the package substrate 110, e.g., the lead frame 110a.

The mold 170 may be provided on the lead frame 110a to encapsulate the first to fifth wafers 122a, 132a, 142a, 152a, and 162a and the passive device 175. For example, the mold 170 may be a single structure for encapsulating the first to fifth wafers 122a, 132a, 142a, 152a, and 162a and the passive device 175 into one.

Furthermore, a connector 180 may be connected to a side of the package substrate 110, e.g., the lead frame 110a. The connector 180 may be exposed from the mold 170 and be used to electrically connect an external product or a main board to the battery protection circuit package 100c.

The battery protection circuit package 100c may be reduced in size by mounting the FGIC module 120, the protection IC module 130, the charge/discharge transistor module 140, the fuse transistor module 150, and the diode module 160 on one lead frame 110a into a single package, and be further reduced in size by mounting the first to fifth wafers 122a, 132a, 142a, 152a, and 162a on the lead frame 110a at the wafer level in a partially stacked structure.

The above-described battery protection circuit packages 100, 100a, 100b, and 100c may be applied to products requiring a small size, e.g., a notebook. When applied to a notebook, the size of the notebook may be reduced and a battery capacity may be increased. In this case, the battery protection circuit packages 100, 100a, 100b, and 100c may also be called notebook battery protection circuit packages.

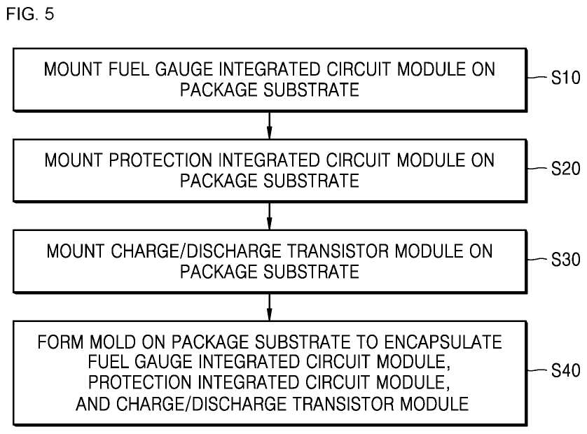

FIG. 5 is a flowchart of a method of fabricating a battery protection circuit package, according to an embodiment of the present invention.

Referring to FIGS. 1 to 5 together, initially, the package substrate 110 processed to form a required circuit configuration, e.g., the lead frame 110a, may be prepared.

Then, the FGIC module 120 may be mounted (operation S10), the protection IC module 130 may be mounted (operation S20), and the charge/discharge transistor module 140 may be mounted (operation S30) on the package substrate 110, e.g., the lead frame 110a. In addition, the fuse transistor module 150 may be further mounted and the diode module 160 may be further mounted on the package substrate 110, e.g., the lead frame 110a.

In this case, the order of mounting may be arbitrarily changed. However, to mount in a stacked structure, a lower structure may be initially mounted and then an upper structure may be mounted.

For example, in FIGS. 3 and 4, the third wafer 142a may be initially mounted on the lead frame 110a and then the second wafer 132a may be mounted on the third wafer 142a. The order of mounting the first wafer 122a, the third wafer 142a, the fourth wafer 152a, and the fifth wafer 162a, which are directly mounted on the package substrate 110, e.g., the lead frame 110a, may be arbitrarily selected.

Optionally, in FIG. 4, the passive devices 175 may be mounted on the lead frame 110a. The passive devices 175 may be mounted on the lead frame 110a before or after the first to fifth wafers 122a, 132a, 142a, 152a, and 162a are mounted.

The above-described mounting process may use a variety of processes, e.g., SMT.

The first to fifth wafers 122a, 132a, 142a, 152a, and 162a may be mounted on the package substrate 110, e.g., the lead frame 110a, at the wafer level. Specifically, the structure of mounting the first to fifth wafers 122a, 132a, 142a, 152a, and 162a and the passive devices 175 is described in detail above in relation to FIGS. 3 and 4.

Optionally, as illustrated in FIG. 4, the connector 180 may be connected to a side of the package substrate 110, e.g., the lead frame 110a.

Then, the mold 150 may be formed on the package substrate 110, e.g., the lead frame 110a, to encapsulate the mounted elements (operation S40). The mold 150 may expose the connector 180 and at least portions of the I/O terminals 102 of the lead frame 110a.

For example, in FIG. 1, a single mold 150 may be formed to encapsulate the FGIC module 120, the protection IC module 130, and the charge/discharge transistor module 140 into one.

As another example, in FIG. 2, a single mold 150 may be formed to encapsulate the FGIC module 120, the protection IC module 130, the charge/discharge transistor module 140, the fuse transistor module 150, and the diode module 160 into one.

As another example, in FIG. 4, a single mold 150 may be formed to encapsulate the FGIC module 120, the protection IC module 130, the charge/discharge transistor module 140, the fuse transistor module 150, the diode module 160, and the passive device 175 into one.

According to the afore-described embodiments of the present invention, a notebook battery protection circuit package capable of achieving a small size to increase a design margin, and a method of fabricating the same may be provided. However, the scope of the present invention is not limited to the above-described effect.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A notebook battery protection circuit package comprising:
a package substrate;
a fuel gauge integrated circuit (FGIC) module mounted on the package substrate;
a protection integrated circuit (IC) module mounted on the package substrate;
a charge/discharge transistor module mounted on the package substrate; and
a mold provided on the package substrate to encapsulate the FGIC module, the protection IC module, and the charge/discharge transistor module into one.

2. The notebook battery protection circuit package of claim 1, wherein the package substrate comprises a lead frame comprising a die mount and input/output (I/O) terminals,
wherein the FGIC module, the protection IC module, and the charge/discharge transistor module are mounted on the die mount of the lead frame, and
wherein the mold exposes at least portions of the I/O terminals.

3. The notebook battery protection circuit package of claim 1, wherein the FGIC module comprises a first wafer having a FGIC device thereon,
wherein the protection IC module comprises a second wafer having a protection IC device thereon, and
wherein the first and second wafers are mounted on the package substrate at a wafer level.

4. The notebook battery protection circuit package of claim 3, wherein the charge/discharge transistor module comprises a third wafer having at least one charge/discharge field effect transistor (FET) thereon, and
wherein the third wafer is mounted on the package substrate at a wafer level.

5. The notebook battery protection circuit package of claim 4, wherein the third wafer is directly mounted on the package substrate, and
wherein the second wafer is mounted on the third wafer.

6. The notebook battery protection circuit package of claim 1, further comprising a fuse transistor module mounted on the package substrate,
wherein the mold further encapsulates the fuse transistor module,
wherein the fuse transistor module comprises a fourth wafer having at least one fuse FET thereon, and
wherein the fourth wafer is mounted on the package substrate at a wafer level.

7. The notebook battery protection circuit package of claim 1, further comprising a diode module mounted on the package substrate,
wherein the mold further encapsulates the diode module,
wherein the diode module comprises a fifth wafer having at least one diode thereon, and
wherein the fifth wafer is mounted on the package substrate at a wafer level.

8. The notebook battery protection circuit package of claim 1, further comprising at least one passive device mounted on the package substrate,
wherein the mold further encapsulates the passive device.

9. The notebook battery protection circuit package of claim 1, further comprising a connector connected to a side of the package substrate and exposed from the mold.

10. A method of fabricating a notebook battery protection circuit package, the method comprising:
mounting a fuel gauge integrated circuit (FGIC) module on a package substrate;
mounting a protection integrated circuit (IC) module on the package substrate;
mounting a charge/discharge transistor module on the package substrate; and
forming a mold on the package substrate to encapsulate the FGIC module, the protection IC module, and the charge/discharge transistor module into one.

11. The method of claim 10, wherein the package substrate comprises a lead frame comprising a die mount and input/output (I/O) terminals,
wherein the FGIC module, the protection IC module, and the charge/discharge transistor module are mounted on the die mount of the lead frame, and
wherein, in the forming of the mold, at least portions of the I/O terminals are exposed from the mold.

12. The method of claim 10, wherein the FGIC module comprises a first wafer having a FGIC device thereon,
wherein the protection IC module comprises a second wafer having a protection IC device thereon, and
wherein, in the mounting of the FGIC module and the protection IC module, the first and second wafers are mounted on the package substrate at a wafer level.

13. The method of claim 12, wherein the charge/discharge transistor module comprises a third wafer having at least one charge/discharge field effect transistor (FET) thereon, and
wherein, in the mounting of the charge/discharge transistor module, the third wafer is mounted on the package substrate at a wafer level.

14. The method of claim 13, wherein the third wafer is directly mounted on the package substrate, and
wherein the second wafer is mounted on the third wafer.

15. The method of claim 11, further comprising mounting a fuse transistor module on the package substrate,
wherein, in the forming of the mold, the mold further encapsulates the fuse transistor module,
wherein the fuse transistor module comprises a fourth wafer having at least one fuse FET thereon, and
wherein, in the mounting of the fuse transistor module, the fourth wafer is mounted on the package substrate at a wafer level.

16. The method of claim 10, further comprising mounting a diode module on the package substrate,
wherein the mold further encapsulates the diode module,
wherein the diode module comprises a fifth wafer having at least one diode thereon, and
wherein, in the mounting of the diode module, the fifth wafer is mounted on the package substrate at a wafer level.

17. The method of claim 10, further comprising mounting at least one passive device on the package substrate,
wherein the mold further encapsulates the passive device.
